(19) United States
(12) Patent Application Publication
(10) Pub. No.: US 2007/0220380 A1
(43) Pub. Date: Sep. 20, 2007

(54) Message system for logical synchronization of multiple tester chips

(75) Inventor: Mamikon Ohanyan, Fremont, CA (US)

Correspondence Address: CREDANCE C/O MURABITO HAO BARNES, LLP, TWO NORTH MARKET STREET, THIRD FLOOR, SAN JOSE, CA, 95113, US

(73) Assignee: Credence Systems Corporation

(21) Appl. No.: 11/385,099

(22) Filed: Mar. 20, 2006

(51) Int. Cl. G01R 31/28

(52) U.S. Cl. 714/724

(57) ABSTRACT

A message system for logically synchronizing a large number of tester chips includes a message pipeline for multiple sets of tester chips. Each set of tester chips includes a delay unit through which messages are communicated to the message pipeline from the set of tester chips and from the message pipeline to the set of tester chips, and a message accumulation unit for temporarily holding the messages communicated from the message pipeline to the set of tester chips. The message pipeline runs at a first clock rate that is governed by a first clock source and the messages are communicated to the set of tester chips from the message accumulation unit at a second clock rate that is governed by a second clock source that is different from the first clock source.

### BACKGROUND OF THE INVENTION

1. Field of the Invention

The present invention generally relates to test systems for electronic devices and more particularly to a message system for logical synchronization of multiple tester chips.

2. Description of the Related Art

The Kalos® 2 test system available from Credence Systems Corporation employs multiple tester chips to provide parallel testing of multiple devices under test (DUTs) or synchronous testing of several hundred DUT pins. The Kalos® 2 test system includes two tester chips on each test board and each tester chip has 48 pins. In the parallel testing mode, the Kalos® 2 test system can employ up to 36 test boards for parallel testing of up to 72 DUTs. In the synchronous testing mode, the Kalos® 2 test system can employ up to nine boards for synchronous testing of up to 864 DUT pins.

To enable the synchronous testing mode, each tester chip of the Kalos® 2 test system is logically synchronized with the other tester chips using a pipelined message system. Each tester chip generates different messages at different points of pipelined operations flow and monitors broadcast messages from the other tester chips. FIG. 1 illustrates the pipelined message system that is implemented in the Kalos® 2 test system.

Each tester chip is connected to a DUT 102 through an interface 104, known in the art as a loadboard, and is configured with a communication unit 110 that is responsible for communicating messages in a daisy chain manner to the other tester chips. The messages are communicated in two directions and so the communication unit 110 includes a right communication unit 112 for communicating messages to the other tester chips in the right direction and a left communication unit 114 for communicating messages to the other tester chips in the left direction.

The tester chip core 120 may generate messages that are to be inserted into the message pipeline, and also receives messages that have been inserted into the message pipeline. In both cases, a delay unit 130 of the tester chip applies an appropriate delay to the message so that a particular message, e.g., global sync fail message, appears at the tester chip core 120 of all tester chips that are part of the same logically synchronous system at the same time.

As shown in FIG. 1, adjacent pairs of right communication devices 112 are connected via two links and adjacent pairs of left communication devices 114 are connected via two links. Each link represents a part of the message pipeline that is clocked at half the DUT's clock rate and is offset from the other link of the pair by one-half DUT cycle, so that in combination they can receive local messages from the tester chip core 120 at the full clock rate of the DUT.

FIG. 2 is a representative block diagram for the communication device 112 or 114 that illustrates the two message pipelines that are clocked at half the DUT's clock rate. They are labeled EVEN and ODD. The EVEN message pipeline includes a flip-flop 210 between its input 205 and its output 215. Another flip-flop 220 is provided between the local message input 201 and the output 215 of the EVEN message pipeline. The ODD message pipeline includes a flip-flop 240 between its input 235 and its output 245. Another flip-flop 250 is provided between the local message input 201 and the output 245 of the ODD message pipeline.

Local messages are alternately inserted into the EVEN and ODD message pipelines. A path interleaving register 255 is toggled high and low with a clock signal that is running at half the DUT's clock rate so that the local message is alternately inserted into the EVEN and ODD message pipelines at the full clock rate of the DUT.

For message flow between communication devices that are physically close, e.g., communication devices that are located on the same board, a path swap register 260 is enabled (i.e., set to 1), so that messages in the EVEN message pipeline are swapped into the ODD message pipeline of the adjacent communication device and messages in the ODD message pipeline are swapped into the EVEN message pipeline of the adjacent communication device. When the path swap occurs in this manner, the effective speed of the messages carried in the pipeline is the full clock rate of the DUT. Message flow between communication devices that are located on different test boards, however, are maintained at half the DUT's clock rate because the test boards are too far apart.

The number of communication devices that can be daisy chained together to create a series of logically synchronized tester chips depends on the amount of message pipeline delay that has been configured into the tester core execution pipeline and the number of tester chips that can be installed on a single test board. In the Kalos® 2 test system, the amount of pipeline delay that is configured into the tester core execution pipeline is 31 ranks, and the number of tester chips that can be installed on a single test board is two. Considering that communication devices on the same test board consume 1 rank between them by employing path swap and communication devices on different test boards consume 2 ranks between them, a total of 21 communication devices on 11 different test boards can be daisy chained together to create a series of 21 logically synchronized tester cores.

### SUMMARY OF THE INVENTION

The present invention provides an improved message system and method that permit message pipelines to be clocked at higher speeds and a greater number of DUT pins to be synchronously tested together. The present invention also provides a test system employing the improved message system and method. Embodiments of the present invention employ two clock domains, the message system clock domain and the DUT clock domain. By using two clock domains, the message system has the flexibility to support higher DUT clock rates.

A message system according an embodiment of the present invention includes a message pipeline through which messages are communicated, a delay unit for a set of test modules, the delay unit including a first delay path through which a local message from the set of test modules is communicated to the message pipeline and a second delay path through which a global message from the message pipeline is communicated to the set of test modules, and a message accumulation unit for the set of test modules connected between the delay unit and the set of test modules, for temporarily holding the global message communicated by the delay unit. The message accumulation unit includes a memory, and messages arriving from the message pipeline are stored in the memory and are read and output to the set of test modules at a later time.

A method for logically synchronizing a plurality of test modules according to an embodiment of the present invention includes the steps of transmitting a global message through a message pipeline in accordance with a first clock rate, communicating the global message from a first position of the message pipeline to a first test module through a delay unit for the first test module and a memory unit for the first test module, and communicating the global message from a second position of the message pipeline to a second test module through a delay unit for the second test module and a memory unit for the second test module. The global message stored in the memory unit for the first test module is communicated to the first test module in accordance with a second clock rate and the global message stored in the memory unit for the second test module is communicated to the second test module in accordance with the second clock rate, wherein the second clock rate is less than the first clock rate.

A test system according to an embodiment of the present invention includes a plurality of tester chips, each configured to be connected to some of the multiple pins of a device under test, and a plurality of programmable devices, each coupled to at least one tester chip and programmed to: (i) receive messages from other programmable devices in a pipelined manner, (ii) transmit messages to other programmable devices in a pipelined manner, (iii) receive messages from the at least one tester chip, and (iv) transmit messages to the at least one tester chip. The programmable devices are configured to transmit messages to one another at a first clock rate that is governed by a first clock source, and the tester chips are configured to operate at a second clock rate that is governed by a second clock source that is different from the first clock source.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 schematically illustrates a message system according to the prior art;

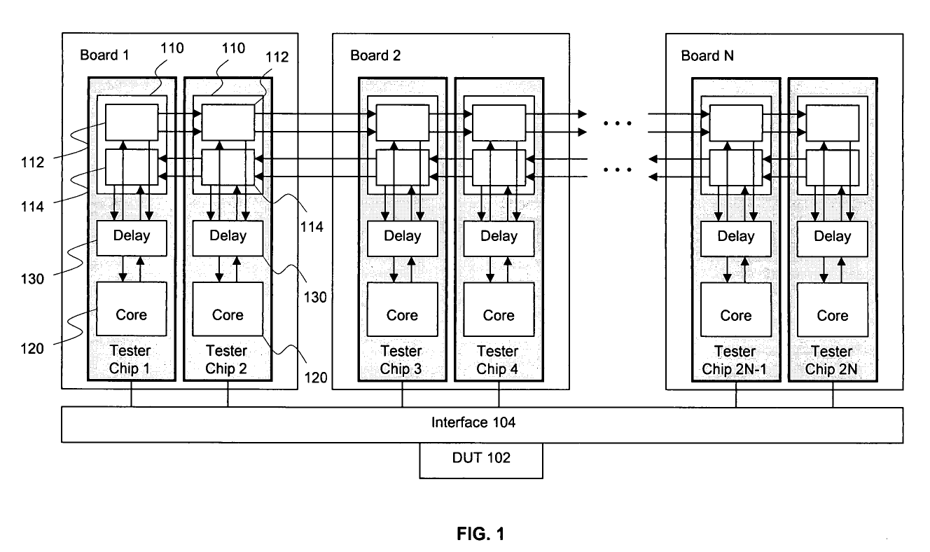

FIG. 2 is a block diagram of a communication device that is used in the message system according to the prior art;

FIG. 3 schematically illustrates a message system according to an embodiment of the present invention;

FIG. 4 is a simplified block diagram of a delay unit shown in FIG. 3;

FIG. 5 is a simplified block diagram of a beginning of clock (BOC) alignment unit shown in FIG. 3; and

FIG. 6 schematically illustrates a message system according to another embodiment of the present invention.

### DETAILED DESCRIPTION

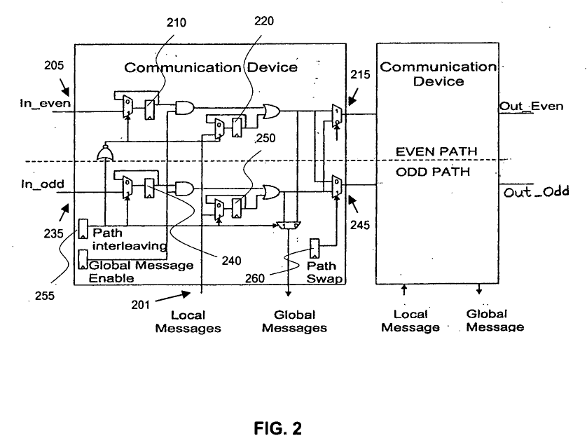

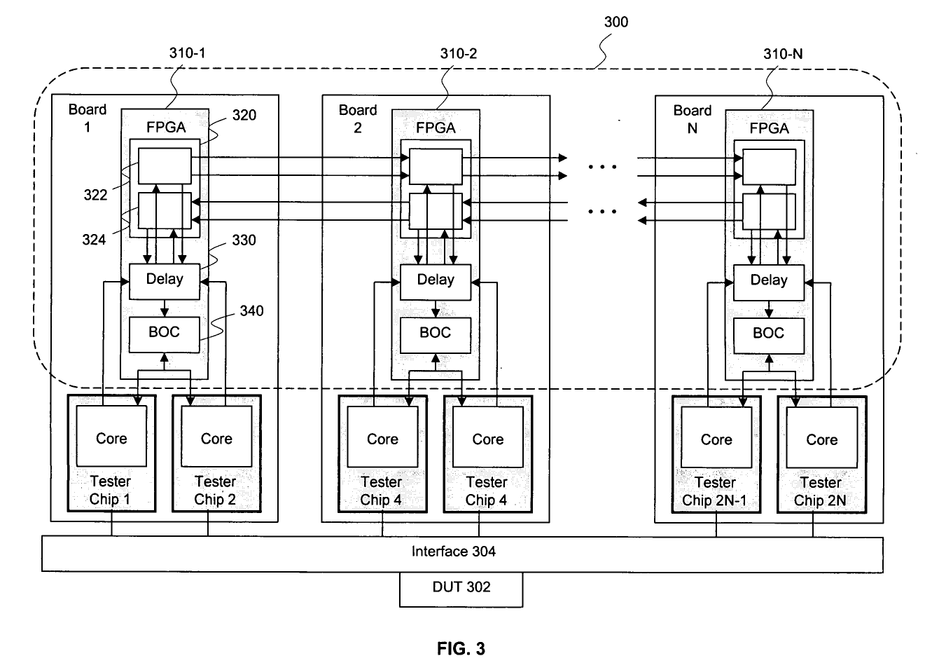

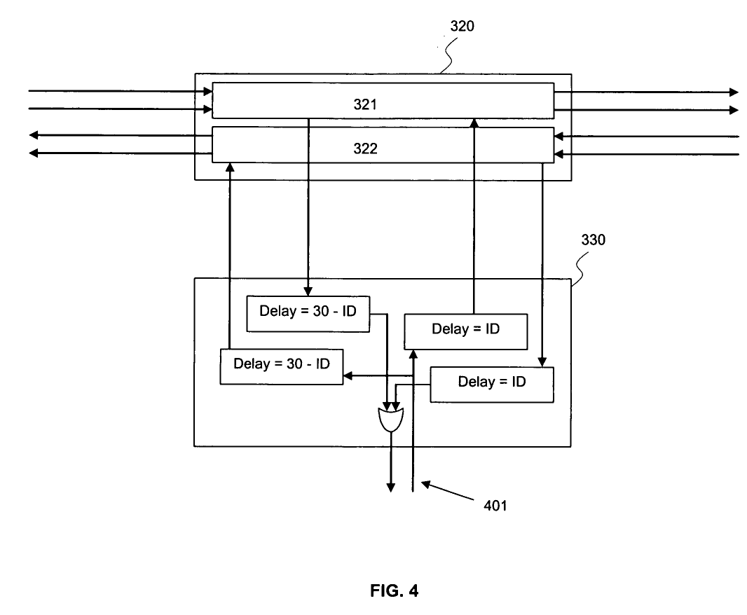

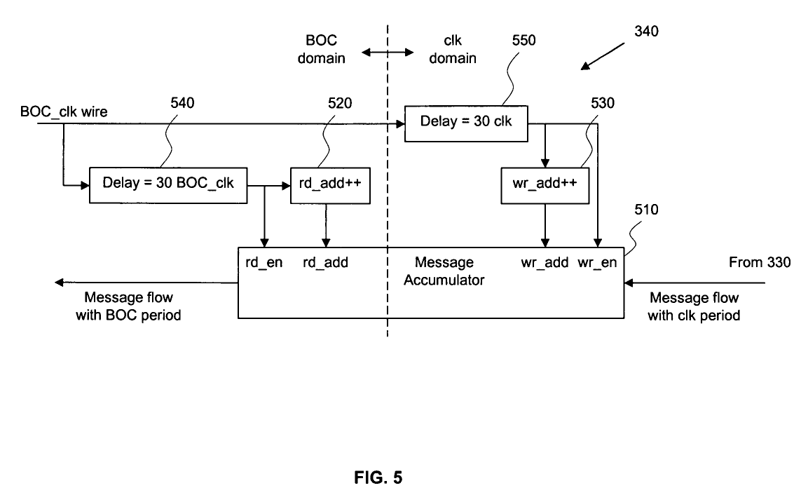

FIG. 3 schematically illustrates a message system 300 according to an embodiment of the present invention. The message system 300 includes a plurality of field programmable gate arrays (FPGAs) 310-1, 310-2, . . . , 310-N interconnected in a daisy chain. Each FPGA 310 is programmed to have a communication device 320 that includes a right communication device 321 and a left communication device 322, a delay unit 330, and a beginning of clock (BOC) alignment unit 340. The right communication device 321 and the left communication device 322 have the same features as the features of the communication device illustrated in FIG. 2. The features of the delay unit 330 and the BOC alignment unit 340 are described below with reference to FIGS. 4 and 5, respectively.

In addition to the message system 300, FIG. 3 illustrates a plurality of tester chips 1 through 2N, each of which corresponds to an application specific integrated circuit (ASIC) that is capable of carrying out many of the automatic test equipment (ATE) functions. Such ASICs are sometimes referred to in the art as a tester-on-chip. Each tester chip is connected to a DUT 302 through a loadboard 304, and is configured with a test execution pipeline that generates at various pipeline ranks, a message (e.g., synchronous fail message, analog controller busy message, or memory unit busy message) that needs to be broadcast globally to all other tester chips, so that the group of logically synchronized tester chips 1 to 2N can branch on shared global events. The test execution pipeline of the tester chip includes two parts. The first part corresponds to ranks associated with pattern generation and timing generation and the second part corresponds to ranks that have been added to the end of the pattern generation and timing generation pipelines to accommodate the delays associated with the pipeline delays of the message system 300.

Each tester chip has an ID corresponding to the FPGA 310 in the daisy chain. In FIG. 3, tester chips 1 and 2 have ID=0; tester chips 3 and 4 have ID=1; and tester chips 2N-1 and 2N have ID=N−1. This ID is used by the FPGA 310 to configure the delay amount of the delay unit 330. FIG. 4 illustrates the delay amounts that are introduced in the transmission and reception paths of the right communication device 321 and the delay amounts that are introduced in the transmission and reception paths of the left communication device 322. In the transmission path of the right communication device 321, a delay=30—ID is added. In the reception path of the right communication device 321, a delay=ID is added. In the transmission path of the left communication device 322, a delay=ID is added. In the reception path of the left communication device 322, a delay=30—ID is added. For simplicity, FIG. 4 shows a single input 401 for messages generated by the tester chips. In the actual implementation, an OR gate is provided to receive at its input the messages generated by multiple tester chips.

In the embodiment illustrated in FIG. 3, the message system 300 is clocked by a clock source that is different from the clock source of the tester chip, which is the clock for the DUT 302. The BOC alignment unit 340 is used to ensure that global messages that are generated by the message system 300 according to the clock rate of its clock source are received by the tester chips, which are operating at the DUT clock rate, at the same time. Also, because the BOC signal is supplied from the tester chip and the BOC alignment unit 340 is configured into the FPGA 310, the FPGA 310 needs to be located close enough to the tester chip so that the BOC signal arrives at the BOC alignment unit 340 within one BOC clock cycle.

FIG. 5 is a simplified block diagram of the BOC alignment unit 340. The BOC alignment unit 340 includes a message accumulator 510. In the embodiment illustrated herein, the message accumulator 510 is a static random access memory (SRAM). The BOC alignment unit 340 stores messages received from the delay unit 330 in the message accumulator 510 at the write address, wr_add, in response to a write enable signal (wr_en). The BOC alignment unit 340 also reads messages stored in the message accumulator 510 at the read address, rd_add, in response to a read enable signal (rd_en), and transmits the messages to the test execution pipeline. The BOC alignment unit 340 further includes a read address incrementing unit 520 and a write address incrementing unit 530. The read address and the write address are initialized at 0 and is incremented respectively by the read address incrementing unit 520 and the write address incrementing unit 530 by one to a maximum of M-1, where M is the size of the message accumulator 510. When M-1 is incremented by one, the address returns to 0.

At the beginning of each DUT clock cycle, a BOC signal is issued and is delayed by 30 DUT clock cycles (BOC_clk) at a read delay unit 540 and by 30 message system clock cycles (clk) at a write delay unit 550. The delay settings in the read delay unit 540 and the write delay unit 550 are set in accordance with the message pipeline delay, and in this embodiment, are set as 30. The BOC signal, after being delayed by 30 DUT clock cycles, causes the read address to be incremented by one at the read address incrementing unit 520 and enables the read from the read address. The BOC signal, after being delayed by 30 message system clock cycles, causes the write address to be incremented by one at the write address incrementing unit 530 and enables the write to the write address.

Pipeline ranks are conserved in the embodiment of FIG. 3, because the use of a single FPGA 310 to carry out the message transport functions of two tester chips saves one pipeline rank. The savings in the pipeline ranks provide the system designer with the flexibility to use the extra ranks to solve any message pipeline timing issues. The extra ranks may also be used for synchronous testing of a greater number of DUT pins. For example, in the embodiment of FIG. 3, up to a maximum of 16 test boards with 32 tester chips can be provided for synchronous testing of up to 1536 DUT pins.

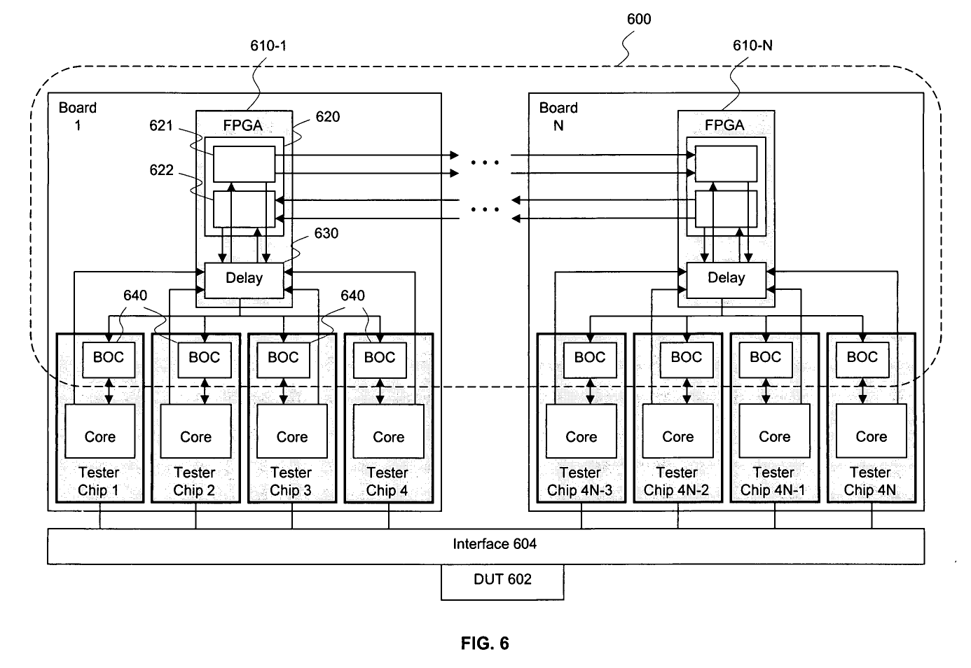

FIG. 6 schematically illustrates a message system according to another embodiment of the present invention. In this embodiment of the message system 600, each of the FPGAs 610-1, . . . , 610-N that are interconnected in a daisy chain is configured with a communication device 620 that includes a right communication device 621 and a left communication device 622, and a delay unit 630. A BOC alignment unit 640 is configured in the tester chip. Each tester chip is connected to a DUT 602 through a loadboard 604.

The right communication device 621 and the left communication device 622 have the same features as the features of the communication device illustrated in FIG. 2, and the delay unit 630 has the same features as the features of the delay unit 330 illustrated in FIG. 4. Also, the BOC alignment unit 640 has the same features as the features of the BOC alignment unit 340 illustrated in FIG. 5, except that the BOC alignment unit 640 is configured in the tester chip and not in the FPGA 610. By doing so, the FPGA 610 can be positioned closer to the edge of the test board so as to reduce the distance between adjacent FPGAs 610. As a result, the message system 600 can be clocked at an increased effective rate of 200 MHz. With the increased clock rate, the message system 600 can support DUT clock rates of up to 200 MHz.

Furthermore, in the embodiment illustrated in FIG. 6, four tester chips share the same communication device 620 and the same delay unit 630, and so at least three pipeline ranks are conserved. In addition, because the message system 600 operates effectively at 200 MHz (instead of 100 MHz), one pipeline rank is saved between test boards. The savings in the pipeline ranks provide the system designer with the flexibility to use the extra ranks to solve any message pipeline timing issues. The extra ranks may also be used for synchronous testing of a greater number of DUT pins. For example, in the embodiment of FIG. 6, up to a maximum of 31 boards with 124 tester chips can be provided for synchronous testing of up to 5952 DUT pins.

In alternative embodiments of the present invention, multiple message systems 300, 600 may be provided, wherein a message system 300, 600 is provided for each type of global messages, e.g., one for synchronous fail messages, one for analog controller busy messages, and one for memory unit busy messages.

While the foregoing is directed to embodiments of the present invention, other and further embodiments of the invention may be devised without departing from the basic scope thereof, and the scope thereof is determined by the claims that follow.

What is claimed is:

1. A message system for a test apparatus having a plurality of test modules coupled to an electronic device, comprising:
a message pipeline through which messages are communicated;
a delay unit for a set of test modules, the delay unit including a first delay path through which a local message from said set of test modules is communicated to the message pipeline and a second delay path through which a global message from the message pipeline is communicated to said set of test modules; and
a message accumulation unit for said set of test modules connected between the delay unit and said set of test modules, for temporarily storing the global message communicated by the delay unit before communicating the temporarily stored global message to said set of test modules.

2. The message system according to claim 1, wherein the message accumulation unit includes a memory, and the global message is stored in the memory and is read from the memory at a later time.

3. The message system according to claim 2, wherein the message pipeline operates at a first clock rate and the memory is accessed for reading at a second clock rate that is less than the first clock rate.

4. The message system according to claim 3, wherein the second clock rate is governed by a clock source for the electronic device.

5. The message system according to claim 1, wherein the local message from said set of test modules is communicated to the delay unit without passing through the message accumulation unit.

6. The message system according to claim 1, wherein the set of test modules includes at least one test module.

7. A method for synchronizing a global message for a plurality of test modules that are coupled to an electronic device, comprising the steps of:
transmitting the global message through a message pipeline in accordance with a first clock rate;
communicating the global message from a first position of the message pipeline to a first test module through a delay unit for said first test module and a memory unit for said first test module; and
communicating the global message from a second position of the message pipeline to a second test module through a delay unit for said second test module and a memory unit for said second test module,
wherein the global message is stored in said memory unit for said first test module and communicated to the first test module in accordance with a second clock rate, and the global message is stored in said memory unit for said second test module and communicated to the second test module in accordance with the second clock rate, and
wherein the first clock rate is greater than the second clock rate.

8. The method according to claim 7, wherein the amount of delay through the delay unit for said first test module is different from the amount of delay through the delay unit for said second test module.

9. The method according to claim 8, wherein the global message is generated from a local message generated by said first test module or said second test module.

10. The method according to claim 7, wherein the first clock rate is governed by a first clock source and the second clock rate is governed by a second clock source that is different from the first clock source.

11. The method according to claim 10, wherein the first clock source is a clock for the message pipeline and the second clock source is a clock for the electronic device.

12. A test system for an electronic device having multiple pins, comprising:
a plurality of tester chips, each configured to be connected to some of the multiple pins of the electronic device; and
a plurality of programmable devices, each coupled to at least one tester chip and programmed to: (i) receive messages from other programmable devices in a pipelined manner, (ii) transmit messages to other programmable devices in a pipelined manner, (iii) receive messages from the at least one tester chip, and (iv) transmit messages to the at least one tester chip,
wherein the programmable devices are configured to transmit messages to one another at a first clock rate that is governed by a first clock source, and the tester chips are configured to operate at a second clock rate that is governed by a second clock source that is different from the first clock source.

13. The test system according to claim 12, wherein each tester chip is configured with a core unit having an execution pipeline and a clock alignment unit having a memory, and the clock alignment unit is configured to store a message transmitted from a corresponding programmable device in the memory at a write address that is incremented once per clock cycle of the second clock source and to transmit a message stored in the memory at a read address that is incremented once per clock cycle of the second clock source.

14. The test system according to claim 13, wherein the clock alignment unit further includes a first delay unit for delaying the incrementing of the write address by a predetermined number of clock cycles of the first clock source, and second delay unit for delaying the incrementing of the read address by a predetermined number of clock cycles of the second clock source.

15. The test system according to claim 12, wherein each programmable device is configured with a communication unit through which messages are transmitted to and received from other programmable devices, and a delay unit through which messages are transmitted between the communication unit and the at least one tester chip.

16. The test system according to claim 15, wherein the delay unit includes a first delay path through which messages from the at least one tester chip are transmitted to the communication unit, and a second delay path through which messages from the communication unit are transmitted to the at least one tester chip.

17. The test system according to claim 16, wherein the amount of delay through the first delay path is different for different ones of said programmable devices, and the amount of delay through the second delay path is different for different ones of said programmable devices, and the total amount of delay through the first delay path and the second delay path is the same for all of said programmable devices.

18. The test system according to claim 15, wherein each programmable device is further configured with a clock alignment unit through which messages are transmitted from the delay unit to the at least one tester chip.

19. The test system according to claim 18, wherein the clock alignment unit includes a memory and stores a message transmitted from the delay unit in the memory at a write address that is incremented once per clock cycle of the second clock source and transmits the message stored in the memory at a read address that is incremented once per clock cycle of the second clock source.

20. The test system according to claim 19, wherein the clock alignment unit further includes a first delay unit for delaying the incrementing of the write address by a predetermined number of clock cycles of the first clock source, and second delay unit for delaying the incrementing of the read address by a predetermined number of clock cycles of the second clock source.
